(19) United States
(12) Patent Application Publication
(10) Pub. No.: US 2021/0159813 A1
(43) Pub. Date: May 27, 2021

(54) FLEXURAL SUSPENSION FOR DELIVERING HAPTIC FEEDBACK TO INTERACTIVE DEVICES

(71) Applicant: Immersion Corporation, San Jose, CA (US)

(72) Inventors: Simon FOREST, Montreal (CA); Peyman Karimi ESKANDARY, Montreal (CA); Kaniyalal SHAH, Fremont, CA (US); Lionel BRAVARD, Montreal (CA); Vahid KHOSHIKAVA, Laval (CA); Majid SHEIKHOLESLAMI, Burlington (CA)

(21) Appl. No.: 16/698,551

(22) Filed: Nov. 27, 2019

(51) Int. Cl. H02N 2/00; B06B 1/06; H01L 41/09; G06F 3/01

(52) U.S. Cl. CPC H02N 2/004; G06F 3/016; H01L 41/0913; B06B 1/0648

(57) ABSTRACT

A support structure includes a fixed frame portion configured to provide a fixed connection point for the support structure. The support structure also includes a suspended frame portion configured to support the interactive device and configured to oscillate in a direction of motion relative to the fixed frame portion due to a force applied to at least one of the fixed frame portion or the suspended frame portion by an actuator configured to provide a haptic effect to the interactive device. Further, the support structure includes one or more support members coupled between the fixed frame portion and the suspended frame portion. The direction of motion is defined by the one or more support members. The one or more support members provide a restoring force that causes the suspended frame portion to undergo harmonic oscillation in the direction of motion in response to the force applied by the actuator.

### FIELD

Embodiments hereof relate to structures, systems and methods for delivering haptic effects to an interactive device.

### BACKGROUND

Electronic device manufacturers strive to produce a rich interface for users. Many devices use visual and auditory cues to provide feedback to a user. In some interface devices, a kinesthetic effect (such as active and resistive force feedback) and/or a tactile effect (such as vibration, texture, and heat) are also provided to the user. Kinesthetic effects and tactile effects may more generally be referred to as “haptic feedback” or “haptic effects”. Haptic feedback can provide cues that enhance and simplify the user interface. For example, vibrotactile haptic effects may be useful in providing cues to users of electronic devices to alert the user to specific events or provide realistic feedback to create greater sensory immersion within an actual, simulated or virtual environment. Such systems may have applications in user interfaces, gaming, automotive, consumer electronics and other user interfaces in actual, simulated or virtual environments.

Certain types of electronic devices, such as visual displays, may not include the necessary hardware to generate haptic effects in order to provide feedback to a user. Likewise, the haptic effects generated by haptic-enabled electronic devices may not be suitable for all applications. For example, these electronic devices may be utilized in interactive applications in which feedback would be useful to a user interacting with the electronic devices. As such, there is a need for systems and devices that deliver haptic effects to electronic devices and the users interacting with the electronic devices.

These and other drawbacks exist with conventional electronic devices. These drawbacks are addressed by embodiments described herein.

### BRIEF SUMMARY

In one aspect, the present disclosure provides a support structure for an interactive device. The support structure includes a fixed frame portion configured to provide a fixed connection point for the support structure. The support structure also includes a suspended frame portion configured to support the interactive device and configured to oscillate in a direction of motion relative to the fixed frame portion due to a force applied to at least one of the fixed frame portion or the suspended frame portion by an actuator configured to provide a haptic effect to the interactive device. Further, the support structure includes one or more support members coupled between the fixed frame portion and the suspended frame portion. The direction of motion is defined by the one or more support members. The one or more support members provide a restoring force that causes the suspended frame portion to undergo harmonic oscillation in the direction of motion in response to the force applied by the actuator.

In aspects, the one or more support members enable motion with one degree of freedom and provides resistance to motion in all other degrees of freedom.

In aspects, a first end of a support member of the one or more support members is coupled to an outer side surface of the fixed frame portion and a second end of the support member is coupled to an inner side surface of the suspended frame portion.

In aspects, the one or more support members include one or more flexural beams.

In aspects, a flexural beam of the one or more flexural beams includes a first structural fillet formed in one or more corners of the first end of the flexural beam where it is coupled to the outer side surface of the fixed frame portion, and a second structural fillet formed in one or more corners of the second end of the flexural beam where it is coupled to the inner side surface of the suspended frame portion.

In aspects, the flexural beam includes a length extending in a direction between the fixed frame portion and the suspended frame portion, a height extending in the direction of motion, and a depth extending perpendicular to the height, and the flexural beam is formed to have a ratio of the depth to the height that allows harmonic oscillation and minimizes the movement of the suspended frame portion in the one or more other directions.

In aspects, the fixed frame portion includes a shelf formed on the outer side surface of the fixed frame portion, and the first end of the flexural beam is coupled to a connection surface of the shelf of the fixed frame portion at an angle of approximately 90 degrees. The suspended frame portion includes a shelf formed on the inner side surface of the suspended frame portion, and the second end of the flexural beam is coupled to a connection surface of the shelf of the suspended frame portion at an angle of approximate 90 degrees. The connection surface of the shelf of the fixed frame portion and the connection surface of the shelf of the suspended frame portion is approximately parallel to the direction of motion, and the direction of motion is approximately 45 degrees to a horizontal axis of the support structure.

In aspects, the flexural beam has at least one of a rectangular cross-section, a circular cross-section, an oval cross-section, and a potato-like cross-section.

In aspects, the suspended frame portion is formed as a hollow frame comprising at least first and second inner side surfaces, the fixed frame portion is formed interior to the suspended frame portion with at least first and second outer side surfaces, and the first and second inner side surfaces of the suspended frame portion oppose the first and second outer side surfaces of the fixed frame portion, respectively.

In aspects, a first of the one or more support members is coupled to the first outer side surface of the fixed frame portion and a second of the one or more support members is coupled to the second outer side surface of the fixed frame portion at a position opposing the first of the one or more support members.

In aspects, the fixed frame portion, the suspended frame portion, and the one or more flexural beams are a single integrated structure.

In aspects, one or more of the fixed frame portion, the suspended frame portion, or the support members are formed of a flexible material.

In aspects, the support structure with an actuator operates as a linear resonant actuator.

In another aspect, the present disclosure provides a method of manufacturing a support structure for an interactive device. The method includes determining specification parameters for a support structure to be manufactured for the interactive device. The support structure includes a fixed frame portion, a suspended frame portion, and one or more support members coupled between the fixed frame portion and the suspended frame portion. The method also includes determining operational parameters of an actuator that is configured to apply a force to at least one of the fixed frame portion or the suspended frame portion to cause the suspended frame portion to oscillate relative to the fixed frame portion in a direction of motion. A configuration of the one or more support members provide a restoring force that causes the suspended frame portion to undergo harmonic oscillation in the direction of motion in response to the force applied by the actuator. Further, the method includes selecting a number of the one or more support members to be included in the support structure and a depth of the one or more support members, the depth extending in a direction approximately parallel to the direction of motion. The method also includes determining a length of the one or more support members and a height of the one or more support members based on the specification parameters, operational parameters, the number of the one or more support members, and the depth of the one or more support members.

In aspects, the method also includes calculating a total spring stiffness of a harmonic system created by the support structure, calculating a spring stiffness of the one or more support members, and calculating an amplitude of displacement of the one or more support members.

In aspects, the specification parameters of the support structure comprise the natural frequency of the harmonic oscillation of the suspended frame portion, an operating frequency of the harmonic oscillation of the suspended frame portion, a mass of the suspended frame portion, a mass of the interactive device, a peak acceleration of the suspended frame portion during movement in the direction of motion, a module of elasticity for a material forming the support structure, and a fatigue strength of the material forming the support structure.

In aspects, the operational parameters of the actuator comprise a spring stiffness of the actuator.

In aspects, the method also includes fabricating a copy of the support structure according to the manufacturing specifications.

In aspects, the copy of the support structure is fabricated as a single integrated structure.

In another aspect, the present disclosure provides a haptic enabled system. The system includes an interactive device, an actuator, and a support structure coupled to the interactive device to provide a haptic effect to the interactive device. The support structure includes a suspended frame portion configured to support the interactive device. To provide the haptic effect, the suspended frame portion oscillates in a direction of motion relative to a fixed frame portion due to a force applied to the suspended frame portion by the actuator. The support structure also includes one or more support members coupled between the suspended frame portion and the fixed frame portion. The direction of motion is defined by the one or more support members. The one or more support members provide a restoring force that causes the suspended frame portion to undergo harmonic oscillation in the direction of motion in response to the force applied by the actuator.

Numerous other aspects are provided.

### BRIEF DESCRIPTION OF DRAWINGS

The foregoing and other features and advantages of the present invention will be apparent from the following description of embodiments hereof as illustrated in the accompanying drawings. The accompanying drawings, which are incorporated herein and form a part of the specification, further serve to explain the principles of various embodiments described herein and to enable a person skilled in the pertinent art to make and use various embodiments described herein. The drawings are not to scale.

FIGS. 1A-1F illustrate a support structure for delivering haptics, according to an embodiment herewith.

FIGS. 2A-2F illustrate theoretical operation of an ideal support system, according to an embodiment herewith.

FIG. 3 illustrates an actuator which can be utilized in the support structure of FIG. 1A, according to an embodiment herewith.

FIGS. 4A and 4B illustrate one example of a support structure, according to an embodiment herewith.

FIG. 5 illustrates another example of a support structure, according to an embodiment herewith.

FIG. 6 illustrates an example of a support structure operating as a linear resonant actuator, according to an embodiment herewith.

FIG. 7 illustrates a method of manufacturing a support structure, according to an embodiment herewith.

### DETAILED DESCRIPTION

Specific embodiments of the present invention are now described with reference to the figures. The following detailed description is merely exemplary in nature and is not intended to limit the present invention or the application and uses thereof. Furthermore, there is no intention to be bound by any expressed or implied theory presented in the preceding technical field, background, brief summary or the following detailed description.

Embodiments disclosed herein are directed to a support structure that enables the delivery of haptic effects to an interactive device, e.g., tablet, display screen, mobile phone, etc. The support structure includes a fixed frame portion for being coupled to a fixed structure (e.g., wall, vehicle surface, etc.) and a suspended frame portion for supporting the interactive device. Haptic effects are delivered to the interactive device by relative motion generated between the fixed frame portion and the suspended frame portion. An actuator delivers a force to the suspended frame portion and/or the fixed frame portion that causes the suspended frame portion to move relative to the fixed frame portion in a direction of motion. The support structure includes flexural beams that connect the suspended frame portion and the fixed frame portion and generate harmonic oscillation in the direction of motion. The flexural beams are constructed and coupled to the fixed frame portion and the suspended frame portion to produce a restoring force in the direction of motion while minimizing motion in other directions of motion.

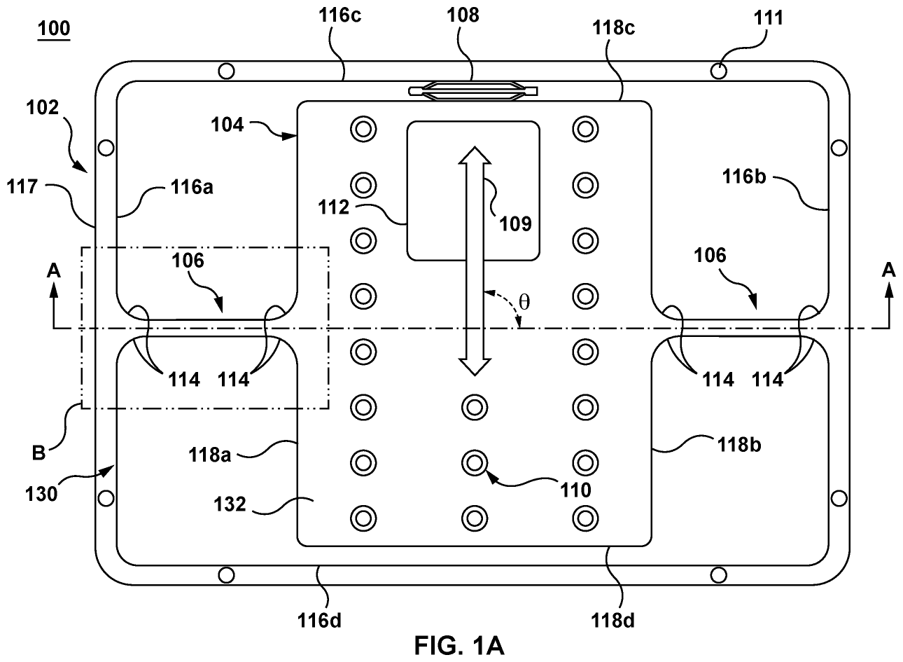

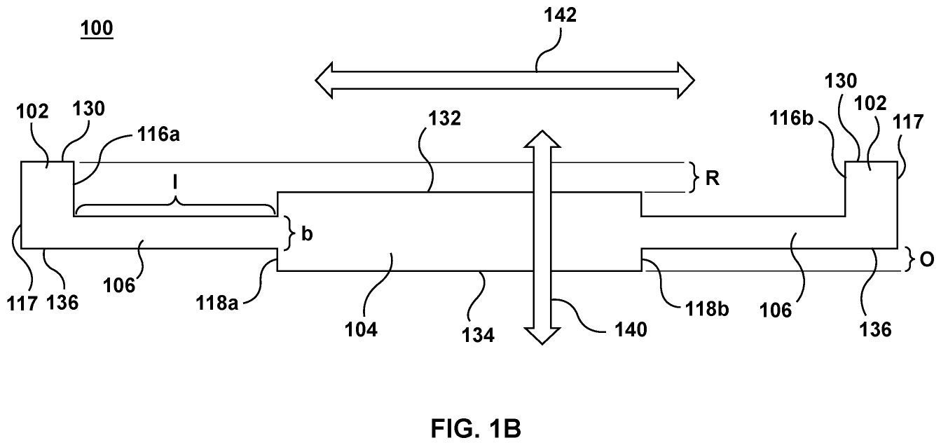

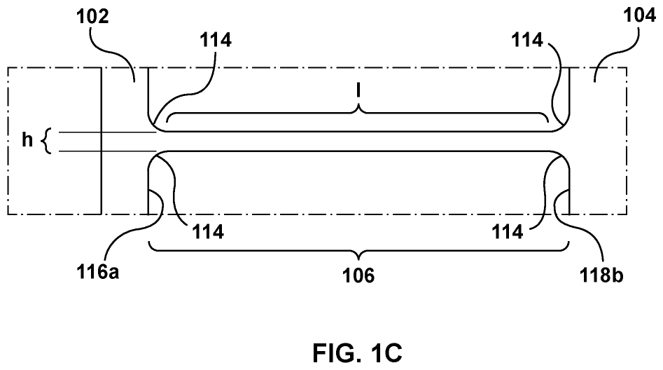

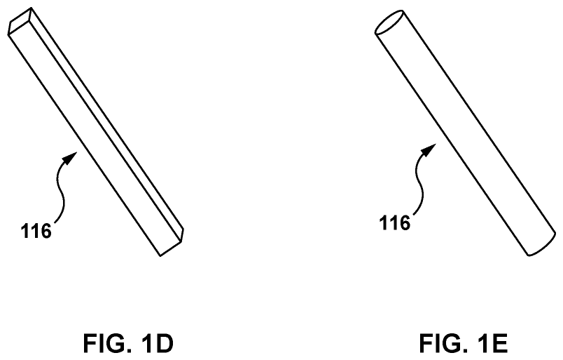

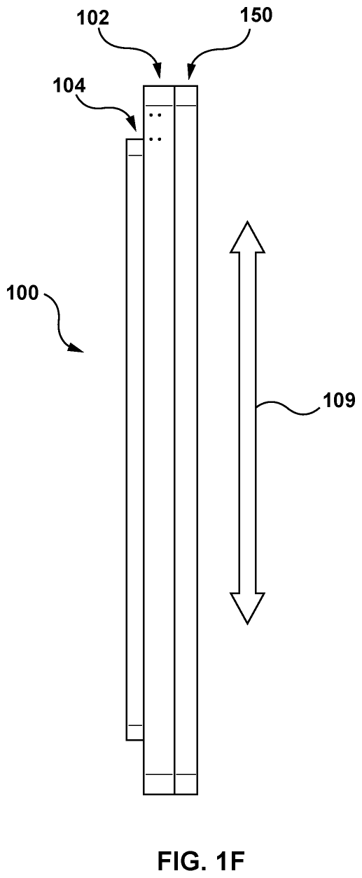

FIGS. 1A-1F illustrate a support structure 100 in accordance with an embodiment hereof. One skilled in the art will realize that FIGS. 1A-1F illustrate one example of a support structure and that existing components illustrated in FIGS. 1A-1F may be removed and/or additional components may be added to the support structure without departing from the scope of embodiments described herein.

As illustrated in FIG. 1A, the support structure 100 includes an outer frame 102 and an inner frame 104. The outer frame 102 is positioned to surround the inner frame 104. In an embodiment, the outer frame 102 can be constructed in the shape of a rectangular frame surrounding the inner frame 104, which is constructed as a rectangular frame. For example, the outer frame 102 can be constructed as a hollow frame that surrounds the inner frame 104. While the outer frame 102 and the inner frame 104 are illustrated as being rectangular frames, one skilled in the art will realize that the outer frame 102 and the inner frame 104 can be constructed in other design shapes, for example, a circular outer frame surrounding a circular inner frame, a square outer frame surrounding a square inner frame, a circular outer frame surrounding a rectangular inner frame, a rectangular outer frame surrounding a circular inner frame, and the like.

The outer frame 102 is coupled to the inner frame 104 by one or more support members. The support members connect the outer frame 102 and the inner frame 104 and generate harmonic oscillation with one degree of freedom in a direction of motion. In embodiments, the one or more support members can include one or more flexural beams 106. In an embodiment, as illustrated in FIG. 1A, the outer frame 102 can be coupled to the inner frame 104 by two (2) flexural beams 106. While FIG. 1A illustrates 2 flexural beams 106, one skilled in the art will realize that the support structure 100 can include any number of additional flexural beams 106 as described herein. Additionally, while the support members are described herein as including the flexural beams 106, one skilled in the art will realize that the support members can include other types of structural supports (e.g., arms, pivots, linkages, springs, or any combination thereof) to achieve the functionality described herein.

In operation, the outer frame 102 can have the potential to move with any degree of freedom relative to the inner frame 104 (or vice versa). For example, the outer frame 102 can move in any direction in the x-direction, y-direction, z-direction, or combination thereof. In embodiments, the flexural beams 106 operate to secure the outer frame 102 to the inner frame 104 and control the movement of the outer frame 102 relative to the inner frame 104 (or vice versa). The flexural beams 106 operate to allow the outer frame 102 to move relative to the inner frame 104 (or vice versa) with one degree of freedom while preventing or limiting movement in all other degrees of freedom. For example, the flexural beams 106 operate to allow the outer frame 102 and the inner frame 104 to move relative to one another with one degree of freedom in a direction of motion 109, e.g., a y-direction of motion as shown in FIGS. 1A-1C.

In embodiments, the materials used to construct the flexural beams 106 and the dimensions of the flexural beams 106 cause the flexural beams 106 to exhibit elasticity in the direction of motion 109. When a force is applied to the outer frame 102 and/or the inner frame 104, the flexural beams 106 are configured to flex in the direction of motion 109 thereby allowing the outer frame 102 and the inner frame 104 to move relative to one another in the direction of motion 109. When the force is removed from the outer frame 102 and/or the inner frame 104, the flexural beams 106 return to their equilibrium position. In embodiments, the force may be provided by an actuator 108 coupled between the outer frame 102 and the inner frame 104. The actuator 108 is configured to provide a force to the outer frame 102 and/or the inner frame 104 to produce relative motion between the outer frame 102 and the inner frame 104 in the direction of motion 109.

In embodiments, the actuator 108 is coupled to the inner frame 104, the outer frame 102, or both to supply the force to the inner frame 104 and/or the outer frame 102. In some embodiments, as illustrated in FIG. 1A, the actuator 108 can be coupled to the outer frame 102 and the inner frame 104. In other embodiment, the actuator 108 can be coupled to either the outer frame 102 or the inner frame 104, and coupled to another structure, e.g., a fixed structure. In any embodiment, the actuator 108 can be coupled to the outer frame 102 and/or the inner frame by removable attachment members (e.g., screws, bolts, rivets, adhesives, etc.), by permanent attachment processes (e.g., soldering, welding, etc.), or by a combination thereof.

While FIG. 1A illustrates the actuator 108 being positioned between top portions (inner side surface 116c and outer side surface 118c) of the outer frame 102 and the inner frame 104, one skilled in the art will realize that the actuator 108 can be positioned between the outer frame 102 and the inner frame 104 at any position that delivers a force in the direction of motion 109, e.g., the actuator's line of force is aligned with the line of movement for the support structure 100. For example, the actuator 108 can be positioned between bottom portions (inner side surface 116d and outer side surface 118d) of the outer frame 102 and the inner frame 104 to deliver a force in the direction of motion 109. Additionally, while FIG. 1A illustrates one actuator 108, one skilled in the art will realize that the support structure 100 can include additional actuators 108 to deliver forces to produce motion, for example, in the direction of motion 109.

As illustrated in FIG. 1A, the direction of motion 109 and the force provided by the actuator 108 are in a direction that is at an angle, θ, relative to an axis, A, of the support structure 100. In response to the force provided by the actuator 108, the flexural beams 106 provide a restoring force in the direction of motion 109 due to the elasticity of the flexural beams 106. Due to the restoring force, the outer frame 102 and the inner frame 104 undergo harmonic oscillation relative to one another when a force is applied by the actuator 108 and removed. In embodiments, the flexural beams 106 deliver a restoring force in a direction, e.g., the direction of motion 109, that is approximately perpendicular to a longitudinal axis of each of the flexural beams 106. Additionally, the flexural beams 106 are configured to reduce motion in other directions of motion, e.g., other degrees of freedom. In embodiments, the materials used to construct the flexural beams 106 and the dimensions of the flexural beams 106 cause the flexural beams 106 to exhibit rigidity in the other directions of motion. As such, the arrangement of the flexural beams 106 (their number and positioning) between the suspended frame and fixed frame defines the degrees of freedom of oscillation for the suspended frame. In certain circumstances, the arrangement will provide one degree of freedom which will provide a linear direction of motion of oscillation for the suspended frame.

While FIG. 1A illustrates the flexural beams 106 being arranged parallel to the axis, A, (e.g., alongside outer side surfaces 118a, 118b of the inner frame 104) to generate motion in the direction of motion 109, one skilled in the art will realize that the flexural beams 106 can be arranged perpendicular to the axis, A, (e.g., along the top and bottom portions 118c, 118d of the inner frame 104) to generate a direction of motion parallel to the axis, A. In this embodiment, the actuator 108 can be positioned at the outer side surfaces 118a, 118b of the inner frame 104 to deliver a force in the direction of motion 109 that is parallel to the axis, A.

In embodiments, the harmonic oscillation produced by the actuator 108 and the flexural beams 106 can be utilized to deliver haptic effects to an interactive device coupled to the support structure 100. As described herein, a haptic effect includes a physical effect and/or sensation that is produced by the actuator 108 and the flexural beams 106, e.g., a vibration, oscillation, etc. For example, the haptic effect can include a sensation of movement to a user's body part touching or interacting with the support structure 100 and/or an interactive device coupled to the support structure 100, e.g., a sensation in the form of a vibration, texture, displacement, force, etc.

To generate a haptic effect, haptic data or a haptic signal can be provided to the actuator 108. As described herein, haptic data or haptic signals include data that instructs or causes the actuator 108 to apply a force and/or forces to the outer frame 102 and/or the inner frame 104 in a predetermined pattern or sequence. For example, the haptic data or haptic signal can include values for physical parameters such as voltage values, frequency values, current values, and the like. Likewise, the haptic data or haptic signal can include relative values that define a magnitude of the haptic effect. In embodiments, the haptic data or haptic signal can be generated and/or supplied by computer system(s), processor(s), driver(s), etc. that are configured to control the operation of the actuator 108. For example, computer system(s), processor(s), driver(s), etc. can store data that relates to various user interactions with an interactive device coupled to the support structure 100 to various haptic effects. When a user interacts, e.g., touches, the interactive device in a particular manner, the computer system(s), processor(s), driver(s), etc. can be configured generate and/or supply the haptic data or haptic signal to the actuator 108 that corresponds to the user's interaction based on the stored relationships. In some embodiments, the interactive device coupled to the support structure 100 can control the operation of the actuator 108.

To deliver the haptic effects, one the outer frame 102 or the inner frame 104 can be coupled to a fixed structure, e.g., wall, table, surface of a vehicle, and the interactive device can be coupled to the other of the outer frame 102 or the inner frame 104. The one of outer frame 102 or the inner frame 104, which is coupled to the fixed structure, can be referred to as the “fixed frame portion,” and the one of the outer frame 102 or the inner frame 104, which is coupled to the interactive device, can be referred to as the “suspended frame portion.” Because the suspended frame portion is not coupled to the fixed structure, the suspended frame portion is free to move in the degree of freedom allowed by the flexural beams 106 relative to the fixed frame portion in response to a force applied by the actuator 108. As such, when the actuator 108 delivers a force to the fixed frame portion and/or the suspended frame portion, the suspended frame portion moves relative to the fixed frame portion. In response to the force provided by the actuator 108, the flexural beams 106 generate a restoring force in the direction of motion 109. Due to the restoring force, the suspended frame portion undergoes harmonic oscillation relative to the fixed frame portion, as the force is applied by the actuator 108 and removed.

In aspects hereof, either the outer frame 102 or the inner frame 104 can operate as the suspended frame portion. Likewise, either the outer frame 102 or the inner frame 104 can operate as the fixed frame portion. For the remainder of the discussion of FIGS. 1A-1F, the outer frame 102 will be discussed as operating as the “suspended frame portion,” and the inner frame 104 will be discussed as operating as the “fixed frame portion.” One skilled in the art will realize that the operation and configuration described below can be equally applied to the outer frame 102 operating as the “fixed frame portion,” and the inner frame 104 operating as the “suspended frame portion.”

Returning to FIG. 1A, the outer frame 102 includes inner side surfaces 116a, 116b, 116c, 116d and a peripheral outer side surface 117. The outer frame 102 also includes a front surface 130. The inner frame 104 includes outer side surfaces 118a, 118b, 118c, 118d. The outer frame 104 also includes a front surface 132. One end of a flexural beam 106 is coupled to the inner side surface 116a, 116b of the outer frame 102, and one end of the flexural beam 106 is coupled to the outer side surface 118a, 118b of the inner frame. Each of the two flexural beams 106 can be positioned to mirror one another from the outer side surfaces 118a, 118b of the inner frame 104, as illustrated in FIG. 1A. In an embodiment, the actuator 108 can be coupled to the inner side surface 116c of the outer frame 102 and the outer side surface 118c of the inner frame 104. The flexural beams 106 operate to produce a restoring force that is approximately perpendicular to longitudinal axes of the flexural beams 106. As illustrated in FIG. 1A, the flexural beams 106 are positioned such that the longitudinal axes of the flexural beams 106 are approximately parallel to the axis, A, to produce an angle, θ, of approximately 90 degrees between the direction of motion 109 relative to the axis, A. One skilled in the art will realize that the flexural beams 106 can be coupled to the outer frame 102 and the inner frame 104 at any angle to produce motion at a corresponding angle relative to the axis, A.

FIG. 1B illustrates a cross-sectional view of the support structure 100 along the line A-A of FIG. 1A and FIG. 1C illustrates an expanded top view B of one of the flexural beams 106. As illustrated in FIGS. 1B and 1C, each of the flexural beams 106 has dimensions of a length, l, (FIG. 1B) a depth, b, (FIG. 1B) and a height, h, (FIG. 1C). In embodiments, values of the length, l, the height, h, and the depth, b, are selected to allow movement in the direction of motion 109, and prevent and/or resist motion in other degrees of freedom, e.g., direction 140 and direction 142 illustrated in FIG. 1B. In embodiments, the value of the depth, b, and a number of the flexural beams 106 can be selected to resist motion in the other directions 140, 142. The values of the length, l, the height, h, and a number of the flexural beams 106 can enable the movement in the desired direction of motion 109. In particular, the parameters of the harmonic oscillation experienced by the suspended outer frame 102 can be controlled by the configuration of the flexural beams 106, e.g., the length, l, height, h, and depth, b, and the number of flexural beams 106, as further described below. In some embodiments, each of the flexural beams 106 can have a same value for the length, l, height, h, and depth, b. In other embodiments, each of the flexural beams 106 can have different values for the length, l, height, h, and/or depth, b.

As illustrated in FIG. 1B, the front surface 130 of the outer frame 102 is offset or spaced from the front surface 132 of the inner frame 104 by a distance, R. The distance, R, allows the outer frame 102 to move in the direction of motion 109 relative to the inner frame 104 without the interactive device 150 contacting the front surface 132 of the inner frame 104. A rear surface 134 of the inner frame 104 is offset from a rear surface 136 of the outer frame 102 by a distance, θ. The distance, O, allows the inner frame 104 to be attached to a fixed structure while allowing the outer frame 102 to move in the direction of motion 109 without contacting the fixed structure.

As illustrated in FIG. 1C, the flexural beam 106 can include structural fillets 114. In embodiments, the length of flexural beam 106 (e.g., length, l) can include the structural fillets 114. The structural fillets 114 are positioned in one or more corners formed by the coupling of the flexural beams 106 and the outer frame 102 and in one or more corners formed by the coupling of the flexural beams 106 and the inner frame 104. In an embodiment, the structural fillets 114 can be positioned in the corners that are in the direction of motion 109. In another embodiment, the structural fillets 114 can be positioned in all the corners formed by the coupling of the flexural beams 106 to the outer frame 102 and/or the inner frame 104. In another embodiment, the structural fillets 114 can be positioned as a continuous circumferential or peripheral structure around the ends of the flexural beams 106.

The structural fillets 114 can be constructed to any size and dimension required by a flexural beam 106 in order to reduce stress concentration when the flexural beams 106 flex. By positioning the structural fillets 114 in at least the direction of motion 109, the structural fillets 114 can reduce stress concentration at the ends of the flexural beams 106 as the outer frame 102 moves in the direction of motion relative to the inner frame 104. In some embodiments, the structural fillets 114 can be formed as part of an integrated or unitary structure with the outer frame 102, the inner frame 104, and the flexural beams 106. In some embodiments, the structural fillets 114 can be formed as separate components that are coupled to the outer frame 102, the inner frame 104, and the flexural beams 106. One skilled in the art will realize that the structural fillets 114 can be formed in any of the corners formed by the coupling of the flexural beams 106, the suspended outer frame 102, and the fixed inner frame 104 to reduce stress concentration. In other embodiments, the structural fillets 114 can be omitted. In these embodiments, the length, l, can correspond to the total length of the flexural beam 106.

As discussed below in further details, each of the flexural beams 106 operates as a spring to provide a restoring force in the direction of motion 109 in response to the force provided by the actuator 108. The flexural beams 106 enable the outer frame 102, which is the suspended frame portion in this aspect, to undergo harmonic oscillation relative to the inner frame 104, which is the fixed frame portion in this aspect. The length, l, of each of the flexural beams 106 and the height, h, of each of the flexural beams 106, and the depth, b, of the flexural beams 106 can be defined as geometry parameters that influence a natural frequency of the support structure 100, a maximum displacement of the outer frame 102, and a damping ratio of the harmonic oscillation experienced by the outer frame 102. A ratio of the length, l, to the height, h, and a ratio of the depth, b, to the height, h, have an impact on an apparent rigidity of the degrees of freedom other than the direction of motion 109, for example, the non-desired directions 140, 142. For example, a larger ratio of the depth, b, to the height, h, can produce more rigidity in each of the flexural beams 106. A smaller ratio of the length, l, to the height, h can produce more rigidity in each of the flexural beams 106.

In embodiments, the flexural beams 106 can be formed in any configuration with any cross-sectional shape, whether regular or random/complex/non-trivial (“potato-like”) geometries. FIGS. 1D and 1E show two examples of configuration and cross-sectional shapes of a flexural beam 106. As illustrated in FIG. 1E, the flexural beam 106 can be configured as a rectangular or square bar. In this example, the flexural beam 106 can have a square or rectangular cross-sectional shape and can be defined by the dimensions of length, l, height, h, and depth, b. As illustrated in FIG. 1F, the flexural beam 106 can be configured as a cylinder. In this example the flexural beam 106 can have a circular or elliptical cross-sectional shape. In this example, the flexural beam 106 can be defined by the dimension of length, l, and radius, r, which replaces the dimensions of height, h, and depth, b. In some embodiments, the flexural beams 106 can be configured to have the same cross-sectional shape. In some embodiments, the flexural beams 106 can be configured to have different cross-sectional shapes.

FIG. 1F illustrates a side view of the support structure 100 coupled to an interactive device 150. In this embodiment, when the actuator 108 is activated, the outer frame 102 moves relative to the inner frame 104 thereby causing the interactive device 150 to move in one degree of freedom, e.g., the direction of motion 109, and resist motion in other degrees of freedom. As such, haptic effects can be delivered to the interactive device 150. For example, haptic effects can be associated with a user's interaction with the interactive device 150. When the user interacts with the interactive device 150, e.g., presses a button, the corresponding haptic effect, e.g., vibration, can be delivered to the interactive device by the motion, e.g., harmonic oscillation, of the outer frame 102. In embodiments, the interactive device 150 can be any type of device in which a user interacts and in which haptic effects can be delivered to the user. For example, the interactive device 150 can include a tablet computer, a laptop computer, a display screen, a mobile phone, etc. While FIG. 1F illustrates an interactive device 150, one skilled in the art will realize that any type of device or surface can be coupled to the support structure 100. For example, a plain surface with a drawing or image can be coupled to the support structure 100. In this example, one or more sensors can detect interaction with the plain surface, e.g., presence of a force or a touch, in a discrete area of the surface, and produce a corresponding haptic effect with the support structure 100.

Returning to FIG. 1A, in some embodiments, the inner frame 104 includes one or more connector holes 110. The connector holes 110 provide a connection point for connecting the inner frame 104 to a fixed surface, in aspects of the invention wherein the inner frame 104 is a fixed frame portion. The connector holes 110 can extend through the inner frame 104 from the front surface 132 to the rear surface 134. The connector holes 110 of the inner frame 104 can be configured to couple the support structure 100 to a fixed surface, e.g., a wall, a surface in a car, a desk, etc. For example, the connector holes 110 can be configured to receive screws, bolts, pins, etc. to couple the inner frame 104 to the fixed surface. While the inner frame 104 is described as including the connector holes 110, one skilled in the art will realize the inner frame 104 can be coupled to a fixed surface using devices and/or processes that do not require the connector holes 110, e.g., welding, soldering, adhesives such as glue, epoxy etc. Likewise, while FIG. 1A illustrates the connector holes 110 as being located on the inner frame 104, when the inner frame 104 operates as the “fixed frame portion,” one skilled in the art will realize that the connector holes 110 can be located on the outer frame 102 (or omitted) when the outer frame 102 operates as the “fixed frame portion.”

In some embodiments, the inner frame 104 includes an access cutout 112. The access cutout 112 can extend through the inner frame 104 from the front surface 132 to the rear surface 134 (as illustrated in FIG. 1B). In some embodiments, the access cutout 112 can be utilized for attaching the actuator 108 to the inner frame 104. In some embodiment, the access cutout 112 can be configured to allow cables and other hardware to be passed through the inner frame 104 without inferring with the relative motion of the inner frame 104 and the outer frame 102. For example, the access cutout 112 can be configured to allow communication cables, power cables, etc. to be passed through the inner frame 104 for connection to the interactive device 150 coupled to the support structure 100. While the inner frame 104 is described as including the access cutout 112, one skilled in the art will realize that the access cutout 112 can be positioned at other locations of the support structure 100, e.g., the outer frame 102, and/or the space between the outer frame 102 and the inner frame 104 can be utilized as the access cutout 112. Likewise, one skilled in the art will realize that the access cutout 112 may be omitted if the interactive device coupled to the support structure 100 does not require physical cables or connections. Further, while FIG. 1A illustrates the access cutout 112 as being located on the inner frame 104, when the inner frame 104 operates as the “fixed frame portion,” one skilled in the art will realize that the access cutout 112 can be located on the outer frame 104 (or omitted) when the outer frame 104 operates as the “fixed frame portion.”

In any of the embodiments described herein, the flexural beams 106 can be constructed of any material that provides elasticity in the direction of motion 109. For example, the flexural beams 106 can be constructed of a metal (e.g., aluminum), a polymeric material (e.g., plastic), a composite material, and combinations thereof. The outer frame 102 can be constructed of any material that provides a rigid or semi-rigid structure to the outer frame 102. For example, the outer frame 102 can be constructed of a metal (e.g., aluminum), a polymeric material (e.g., plastic), a composite material, and combinations thereof. The inner frame 104 can be constructed of any material that provides a rigid or semi-rigid structure to the inner frame 104. For example, the inner frame 104 can be constructed of a metal (e.g., aluminum), a polymeric material (e.g., plastic), a composite material, and combinations thereof.

In some embodiments, the support structure 100 (the outer frame 102, the inner frame 104, and the flexural beams 106) can be constructed or fabricated as a single integrated structure. For example, the outer frame 102, the inner frame 104, and the flexural beams 106 can be milled from a single piece of material (e.g., metal), cast or molded into a unitary structure. Likewise, for example, the outer frame 102, the inner frame 104, and the flexural beams 106 can be three-dimensionally (3D) printed as a unitary structure. In some embodiments, the outer frame 102, the inner frame 104, and the flexural beams 106 can be fabricated separately, whether from same or different materials, and assembled to form the support structure 100.

In any of the embodiments described herein, the actuator 108 can be or include any suitable output device known in the art. For example, the actuator 108 can include thin film actuators, such as macro-fiber composite (MFC) actuators, piezoelectric material actuators, smart material actuators, electro-polymer actuators, and others. The actuator 108 can further include inertial or kinesthetic actuators, eccentric rotating mass (“ERM”) actuators in which an eccentric mass is moved by a motor, linear resonant actuators (“LRAs”), vibrotactile actuators, shape memory alloys, and/or any combination of actuators.

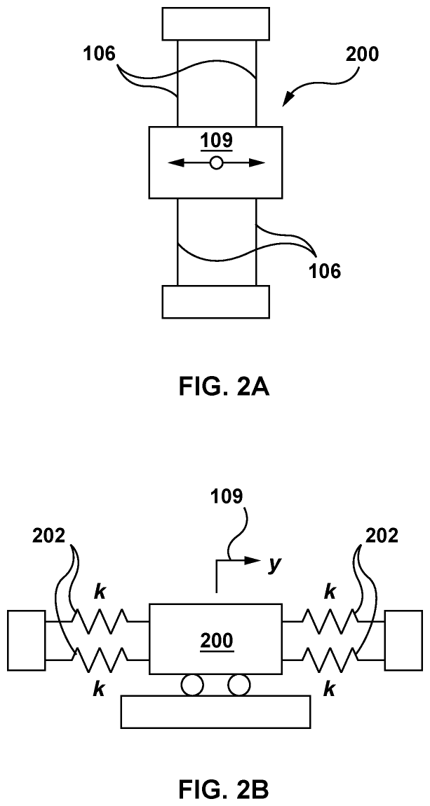

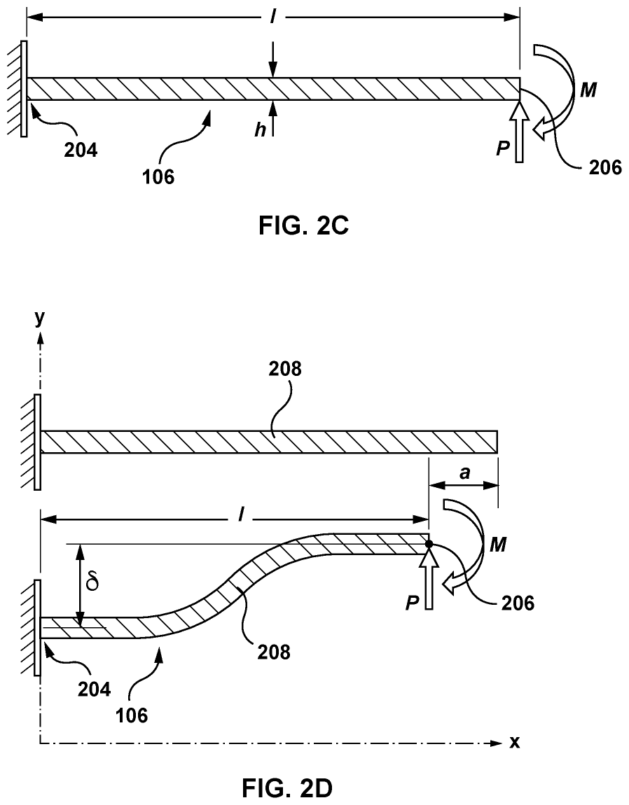

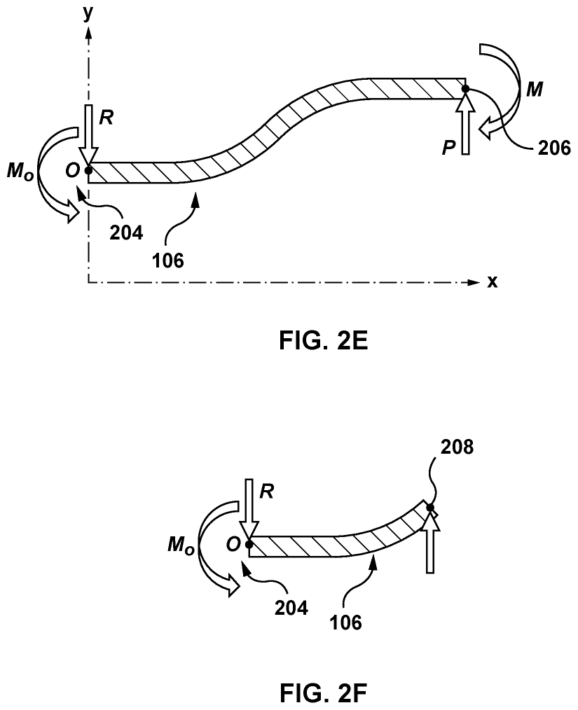

As discussed above, the flexural beams 106 can be configured to flex to allow the suspended frame portion (the outer frame 102 or the inner frame 104) to move and undergo harmonic oscillation in the direction of motion 109 relative to the fixed frame portion (the outer frame 102 or the inner frame 104). The parameters of the harmonic oscillation experienced by the suspended frame portion (the outer frame 102 or the inner frame 104) can be controlled by configuration of the flexural beams 106, e.g., the length, l, height, h, and depth, b, and the number of flexural beams 106. To understand the relationship between the configuration of the flexural beams 106 and the harmonic oscillation, the flexural beams 106 can be modeled as an ideal flexural beam system. FIGS. 2A-2G illustrate an ideal flexural beam system in accordance with a non-limiting embodiment hereof. One skilled in the art will realize that FIGS. 2A-2G illustrates one example of a theoretical operation of the support structure 100 and that the components required to understand the theoretical operation are illustrated in FIGS. 2A-2F.

As discussed above, the support structure 100 includes multiple flexural beams 106 that control movement of the suspended frame portion relative to the fixed frame portion in one direction of motion 109 while providing stiffness in other directions in which motion is not desired. In operation, each of the flexural beams 106 (along with the actuator 108) acts as a spring 202 of stiffness, Kₜ, that moves a body 200 (e.g., suspended frame portion, attached interactive device, flexural beams, and portion of the actuator 108) of mass, m, as shown in FIGS. 2A and 2B. The support structure 100 then creates a simple harmonic system that can resonate a natural frequency, fₙ.

In operation, a flexural beam 106 can be modeled as a fixed guided end beam, as shown in FIG. 2C. In this model, a fixed end 204 of the flexural beam 106 corresponds to an end of the flexural beam 106 that is coupled to the fixed frame portion, and a tip 206 of the flexural beam 106 corresponds to an end of the flexural beam 106 that is coupled to the suspended frame portion. P is the force applied at the tip 206 of the flexural beam 106 (e.g., from the actuator 108), and M is the moment applied at the tip 206. As discussed earlier, l is the length of the flexural beam 106, h is the height of the flexural beam 106, and b is the depth of the flexural beam 106.

As shown in FIG. 2D, the force, P, applied at the tip 206 causes the flexural beam 106 to deform. The force, P, applied at the tip 206 creates a flexion of the flexural beam 106. The moment, M, at the tip 206 corrects the angle of the tip 206 so that it is kept parallel to the fixed end 204. The combination of both is a translation of the tip 206 by a distance, δ, in the y-axis (direction of motion 109) and, a, in the x-axis (other directions of motion), where a<<1. Due to the construction and design, the flexural beam 106 shows an inflexion point 208 at the center of its length, l, when deformed. The inflexion point 208 is a point where all the moments cancel out and only shear force is present.

FIG. 2E shows a free body diagram of the flexural beam 106 when deformed. The fixed end 204 is replaced by a moment, M₀, and a reaction force R at point, O. The summation of forces and moments can be calculated using the following equations:

ΣFₓ=0 (1)

ΣF_{y}=O=P−R⇒R=P (2)

ΣM_{/0}==Mₒ−M+Pl⇒M=M₀+Pl (3)

Because the flexural beam 106 has the inflexion point 208 at the center of its length, l, it is possible to cut the flexural beam 106 at the center and use the fact that there is no moment at the center to evaluate M₀, as illustrated in FIG. 2G. Using these assumptions, the summation of forces and moments can be calculated using the following equations:

$$\begin{matrix}\sum {F}_{x} = 0 & ( 4 ) \\ \sum {F}_{y} = 0 = P - R R = P & ( 5 ) \\ \sum M / 0 = 0 = {M}_{o} + \frac{Pl}{2} {M}_{0} = - \frac{Pl}{2} & ( 6 )\end{matrix}$$

Applying to equation (3) the M can be written as

$$M = {M}_{0} + Pl M = \frac{Pl}{2} \qquad ( 7 )$$

Using linear theory of a beam, one can calculate the maximum deformation of the flexural beam 106, happening at the tip 206, as a function of the geometry of the flexural beam 106 and material properties of material used to form the flexural beam 106, as described in Roak's Formulas for Stress and Strain, Warren Young, et. al., 7^{th} ed., p 189, FIG. 1b (2002). The maximum deformation of the flexural beam 106 can be given by the equation:

$$δ = \frac{{Pl}^{3}}{12 EI} \qquad ( 8 )$$

where δ is the deformation of the tip 206 in millimeters (mm), E is the modulus of elasticity of the material of the flexural beam 106 in megapascals (MPa), I is the section inertia give in mm⁴, l is the length of the flexural beam 106 in mm, and P is the force applied at the tip 206 in Newtons (N).

The section inertia, I, can be given by the equation:

$$l = \frac{b {h}^{3}}{12} \qquad ( 9 )$$

where b is the width of the flexural beam 106 in mm and h is the height of the flexural beam 106 in mm.

The spring stiffness, K, of the flexural beam 106 can be evaluated from the equation of, δ, by isolating the parameters to derive an equation in the form of Hook's law as follows:

$$P = K δ ⇒ \frac{P}{δ} = K = \frac{12 EI}{{l}^{3}} \qquad ( 10 )$$

where K is the beam spring stiffness of the flexural beam 106 in N/mm.

The maximum constraint (fatigue strength) in the flexural beam 106 is found at any end and is given by the equation:

$$σ = \frac{M c}{I} = \frac{Plh}{4 I} \qquad ( 11 )$$

where σ is the maximum constraint of the flexural beam 106 in MPa, and c is the distance from the neutral line of the flexural beam 106 and is maximum at half height h/2 of the flexural beam 106. These equations can be used to evaluate the geometry of the flexural beam 106 from the predefined parameters: K, δ, σ, b, and E.

The natural frequency of the support structure 100 is given by:

$$2 π {f}_{n} = \sqrt{\frac{{K}_{t}}{m}} \qquad ( 12 )$$

wherein fₙ is the natural frequency of the support structure 100 is in Hertz (Hz), m is the mass of the support structure 100 in kilograms (kg), and Kₜ is a total spring stiffness of the support structure 100 in N/M.

Note that Kₜ is a summation of all the individual beam spring stiffness, K, of the flexural beam 106 and spring stiffness of the actuator 108, K_{A}, because they are parallel to each other and given by the equation:

$${K}_{t} = ( n K + {K}_{A} ) * 1000 \frac{mm}{m} \qquad ( 13 )$$

where n is the number of the flexural beams 106.

Because fₙ and m will be given by specifications of the support structure, equation (12) can be rewritten in terms of Kₜ:

Kₜ=m(2πfₙ)² (14)

Knowing n, K_{A}, and Kₜ, K can be given by:

$$K = \frac{{K}_{t} * ( \frac{1}{1000} ) - {K}_{A}}{n} \qquad ( 15 )$$

where Kₜ is given in N/m and 1 m/1000 mm is a conversion factor to be consistent with the units of K_{A} which may be given in N/mm.

The displacement of the suspended frame portion is directly proportional to the acceleration and the frequency of the support system 100. The equations of motion for a harmonic system can be given by:

x=A sin(ωt)⇒Displacement of a body (16)

\dot{x}=Aωcos ωt⇒Speed of a body (17)

\ddot{x}=−Aω² sin ωt⇒Acceleration of a body (18)

Where x, \dot{x}, and \ddot{x} are the position, speed and acceleration of a body, respectively, A is the amplitude of displacement in mm, co is the angular speed of the signal in radians per second (rad/s), t is the time in s.

From equation (18) for acceleration, the amplitude of sine wave is Aω². Assuming that the peak acceleration of the support structure 100 is aₚ, the acceleration can be rewritten as:

$$\ddot{x} = {a}_{p} = A {ω}^{2} ⇒ A = \frac{{a}_{p}}{{ω}^{2}} \qquad ( 19 )$$

Because ω=2πf and A=δ, the relation between the operating frequency, acceleration expected, and amplitude of displacement is given by the equation:

$$δ = \frac{{a}_{p}}{{( 2 π f )}^{2}} \qquad ( 20 )$$

From equation (20), the largest value of δ is found when the acceleration aₚ is maximal and f is minimal.

From the equations above, the parameters l and h can be derived. In equation (10) for the beam spring stiffness, K, I can be replaced by its expression from equation (9):

$$K = \frac{12 EI}{{l}^{3}} = \frac{12 E ( \frac{b {h}^{3}}{12} )}{{l}^{3}} = \frac{E b {h}^{3}}{{l}^{3}} \qquad ( 21 )$$

The expression of the constraint (11), σ, can be rewritten by replacing P as a function of K and replacing I with its expression from equation (9):

$$σ = \frac{P l h}{4 l} = \frac{( K δ ) l h}{4 ( \frac{b {h}^{3}}{12} )} = \frac{( \frac{E b {h}^{3}}{{l}^{3}} δ ) 12 l h}{4 b {h}^{3}} = \frac{3 E δ h}{{l}^{2}} \qquad ( 22 )$$

Equation (22) can then be rewritten in terms of h:

$$σ = \frac{3 E δ h}{{l}^{2}} ⇒ h = \frac{σ {l}^{2}}{3 E δ} \qquad ( 23 )$$

The valve of l can then be derived from equations (21) and (23) for K and h:

$$\begin{matrix}K = \frac{{Ebh}^{3}}{{l}^{3}} = \frac{Eb ( \frac{σ {l}^{2}}{3 E δ} )}{{l}^{3}} & ( 24 ) \\ K = \frac{Eb {σ}^{3} {l}^{3}}{27 {E}^{3} {δ}^{3} {l}^{3}} = \frac{b {σ}^{3} {l}^{3}}{27 {E}^{2} {δ}^{3}} & ( 25 )\end{matrix}$$

Solving for l:

$$l = {( \frac{27 K {E}^{2} {δ}^{3}}{b {σ}^{3}} )}^{1 / 3} \qquad ( 26 )$$

Based on the above discussion, a list of parameters and equations can be selected to determine the dimensions of the flexural beams 106 for different configuration and specifications of the support structure 100:

$$\begin{matrix}{K}_{t} = {m ( 2 π {f}_{n} )}^{2} & ( 27 ) \\ K = \frac{{K}_{t} * ( \frac{1}{1000} ) - {K}_{A}}{n} & ( 28 ) \\ δ = \frac{{a}_{p}}{{( 2 π f )}^{2}} & ( 29 ) \\ l = {( \frac{27 {KE}^{2} {δ}^{3}}{b {σ}^{3}} )}^{1 / 3} & ( 30 ) \\ h = \frac{σ {l}^{2}}{3 E δ} & ( 31 )\end{matrix}$$

Using equations (27)-(31), a support structure 100 can be designed and manufactured to accommodate any type of interactive device to which haptic effects can be delivered. In embodiments, for a particular interactive device, specification parameters and operational parameters can be determined for a support structure 100 to deliver haptic effects to the interactive device. Equations (27)-(31) can then be utilized to calculate the dimensions of the flexural beams 106. As described herein, specification parameters can include any variable and/or constraint associated with the structural requirements and the motion of the support structure 100. As described herein, operational parameters can include any variable and/or constraint associated with the operation of the actuator 108. Table 1 illustrates the parameters that may be selected and calculated for designing and manufacturing the support structure 100.

TABLE 1
Parameters for Designing a Support Structure

| Parameter | Description | Determination |
|---|---|---|
| fₙ | Natural frequency of | Selected according to the |
| | the support structure | requirements of delivering |
| | | haptic effects to the inter- |
| | | active device (e.g., motion |
| | | that conveys haptic effect) |
| m | Mass of the body under- | Selected according to the |
| | going harmonic oscillation | requirements of supporting |
| | (e.g., suspended frame | the interactive device (e.g., |
| | and flexural beams) | dimensions of the support |
| | | structure, weight of material |
| | | used to construct the support |
| | | structure, weight of interactive |
| | | device, weight of portions of |
| | | the actuator) |
| Kₜ | Total spring stiffness of | Determined from equation (27) |
| | the support structure | |
| K_{A} | Actuator spring stiffness | Determined from operational |
| | | parameters of the actuator |
| n | Number of flexural beams | Selected according to the |
| | | requirements of delivering |
| | | haptic effects to the inter- |
| | | active device and/or manu- |
| | | facturing requirements (e.g., |
| | | predefined, selected through |
| | | testing, selected from manu- |
| | | facturing constraints, etc.) |
| K | Beam spring stiffness | Determined from equation (28) |
| aₚ | Peak acceleration | Selected according to the |
| | | requirements of delivering |
| | | haptic effects to the inter- |
| | | active device (e.g., motion |
| | | that conveys haptic effect) |
| | | and/or determined from |
| | | operational parameters of |
| | | the actuator |
| f | Operating frequency | Selected according to the |
| | | requirements of delivering |
| | | haptic effects to the inter- |
| | | active device (e.g., motion |
| | | that conveys haptic effect) |
| | | and/or determined from |
| | | operational parameters of |
| | | the actuator |
| δ | Flexural beam deformation | Determined from equation (29) |
| E | Module of elasticity | Determined from properties |
| | | of materials used to construct |
| | | the flexural beams |
| σ | Fatigue strength | Determined from properties |
| | | of materials used to construct |
| | | the flexural beams |
| b | Flexural beam depth | Selected according to the |
| | | requirements of delivering |
| | | haptic effects to the inter- |
| | | active device, the requirements |
| | | of reducing motion in other |
| | | directions of motion, and/or |
| | | manufacturing requirements |
| | | (e.g., predefined, selected |
| | | through testing, selected |
| | | from manufacturing constraints, |
| | | etc.) |
| l | Flexural beam length | Determined from equation (30) |
| h | Flexural beam height | Determined from equation (31) |

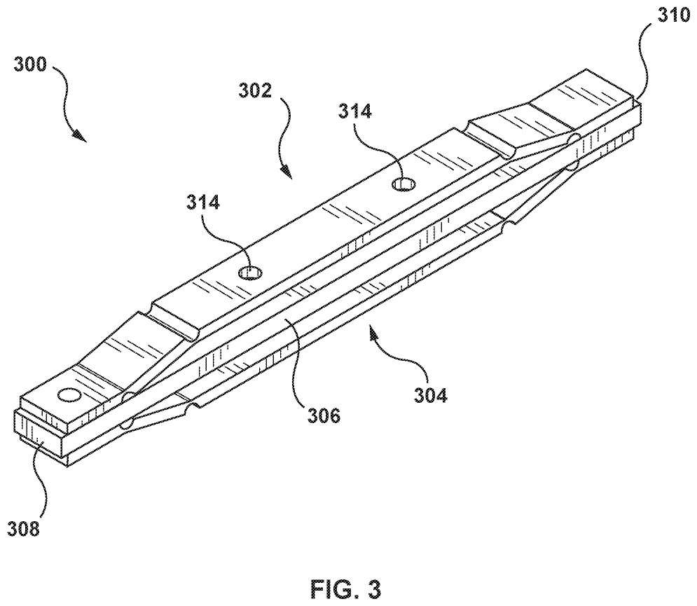

FIG. 3 illustrates an actuator 300 in accordance with an embodiment hereof. One skilled in the art will realize that FIG. 3 illustrates one example of an actuator and that existing components illustrated in FIG. 3 may be removed and/or additional components may be added to the support structure without departing from the scope of embodiments described herein. In some embodiments, the actuator 300 may be a version of the TDK® PowerHap™ piezo actuator, such as the PowerHap™ 6005 H090V120 of haptic actuator from TDK®.

As illustrated, the actuator 300 includes a top displacement amplifier 302 and a bottom displacement amplifier 304. The top displacement amplifier 302 and the bottom displacement amplifier 304 are positioned on opposite sides of a displacement member 306. The top displacement amplifier 302 and the bottom displacement amplifier 304 are designed and manufactured of a material that amplifies the motion produced by the displacement member 306. In embodiments, the top displacement amplifier 302 and the bottom displacement amplifier 304 can be constructed in a bow design and manufactured of a metal (e.g., titanium). One skilled in the art will realize the top displacement amplifier 302 and the bottom displacement amplifier 304 can be constructed in any design and manufactured of any material that amplifies the movement of the displacement member 306.

The displacement member 306 includes a positive outer metallization 308 and a negative outer metallization 310 formed at opposing ends of the displacement member 306. In operation, the displacement member 306 is configured to displace (e.g., move) when a potential difference is applied across the positive outer metallization 308 and the negative outer metallization 310. For example, when a haptic signal is applied to the positive outer metallization 308 and the negative outer metallization 310, the displacement member 306 can displace according to the pattern or sequence of the haptic signal. In embodiments, the displacement member 306 can be constructed of a piezoelectric material (e.g., a lead zirconium titanate ceramic). One skilled in the art will realize the displacement member 306 can be constructed in any design and manufactured of any material that produces movement in response to a haptic signal.

The top displacement amplifier 302 can include connection holes 314. The bottom displacement amplifier 304 can also include connection holes (not shown). The connection holes 314 can extend through the top displacement amplifier 302 from a top surface to a bottom surface. The connection holes (not shown) for the bottom displacement amplifier 304 can extend through the bottom displacement amplifier 304 from a top surface to a bottom surface. The connection holes 314 can be configured to couple the actuator 300 to the outer frame 102 and the inner frame 104. For example, the connection holes 314 can be configured to receive screws, bolts, pins, etc. to couple the actuator 300 to the outer frame 102 and the inner frame 104. While the top displacement amplifier 302 and the bottom displacement amplifier 304 are described as including the connection holes 314, one skilled in the art will realize the actuator 300 can be coupled to the outer frame 102 and the inner frame 104 using connection devices and processes that do not require the connection holes 314, e.g., welding, soldering, adhesives such as glue, epoxy, etc.

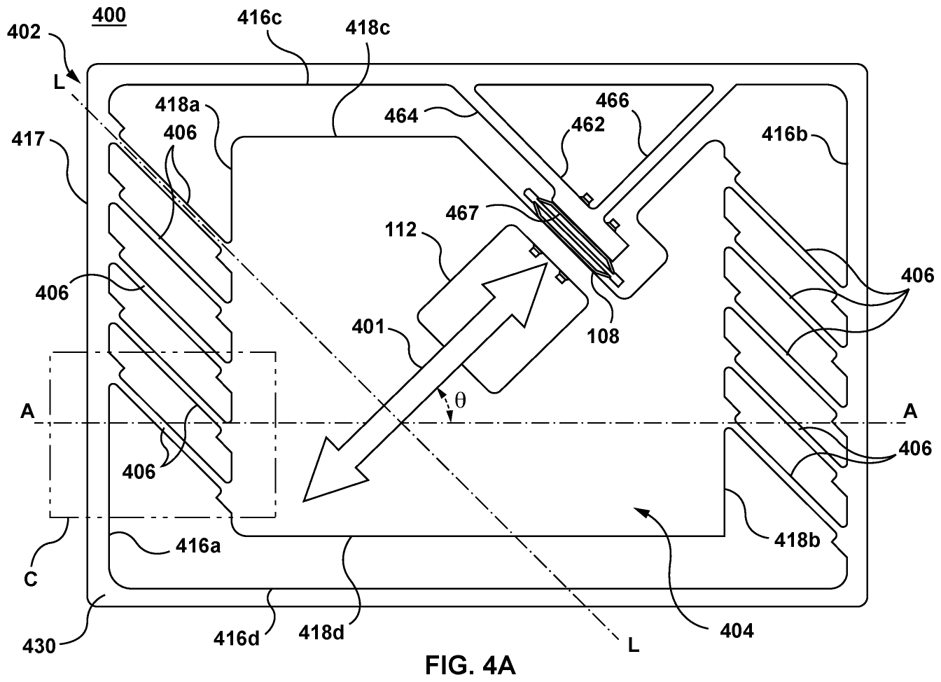

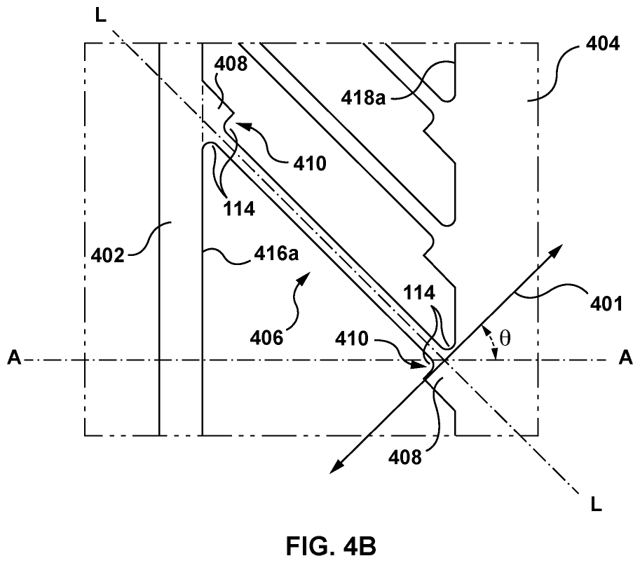

As discussed above, the flexural beams 106 can be positioned in the support structure to produce movement with one degree freedom in a direction of motion at any angle, θ, while restricting movement in all other degrees of freedom FIGS. 4A and 4B illustrate another example of a support structure 400 in accordance with an embodiment hereof. One skilled in the art will realize that FIGS. 4A and 4B illustrate one example of a support structure and that existing components illustrated in FIGS. 4A and 4B may be removed and/or additional components may be added to the support structure without departing from the scope of embodiments described herein. In FIGS. 4A and 4B, a description of components with the same reference number can be found above in the description of FIGS. 1A-1F, and the same description applies to these components in FIGS. 4A and 4B.

As illustrated, the support structure 400 includes an outer frame 402 and an inner frame 404. In this embodiment, the outer frame 402 will be discussed as operating as the “suspended frame portion,” and the inner frame 404 will be discussed as operating as the “fixed frame portion.” The outer frame 402 is coupled to the inner frame 404 by a number of support members (e.g., flexural beams 406). In this embodiment, the outer frame 402 is coupled to the inner frame 404 by ten (10) flexural beams 406. The arrangement of the flexural beams 406 (their number and positioning) between the suspended frame (e.g., the outer frame 402) and fixed frame (e.g., inner frame 404) defines the degrees of freedom of oscillation for the suspended frame. In certain circumstances, the arrangement will provide one degree of freedom which will provide a linear direction of motion of oscillation for the suspended frame. In this embodiment, the flexural beams 406 produce motion with one degree of freedom in a direction of motion 401 relative to the axis, A, and an angle, θ. That is, the flexural beams 406 produces harmonic oscillation in the direction of motion that is approximately perpendicular to a longitudinal axis, L, of each of the flexural beams 406.

The outer frame 402 includes inner side surfaces 416a, 416b, 416c, 416d and a peripheral outer side surface 417. The outer frame 402 also includes a front surface 430. The inner frame 404 includes outer side surfaces 418a, 418b, 418c, 418d. The outer frame 404 also includes a front surface 432. One end of a flexural beam 406 is coupled to the inner side surface 416a, 416b of the outer frame 402, and one end of the flexural beam 406 is coupled to the outer side surface 418a, 418b of the inner frame 404. Each of the flexural beams 406 can be positioned having a longitudinal axis, L, in the same direction to produce the movement in the direction of motion 401, as illustrated in FIG. 4A.

While FIG. 4A illustrates the flexural beams 406 being arranged alongside outer side surfaces 418a, 418b of the inner frame 404 to generate motion in the direction of motion 401, one skilled in the art will realize that the flexural beams 106 can be along the outer side surfaces 418c, 418d of the inner frame 404 to generate a direction of motion in a different direction. In this embodiment, the actuator 108 can be positioned at the outer side surfaces 418a, 418b of the inner frame 404 to deliver a force in the direction of motion 401. Likewise, an angle between the longitudinal axis, L, and the inner side surface 416a, 416b, and the outer side surface 418a, 418b, can be changed to change the direction of motion 401.

In this embodiment, the actuator 108 is coupled to the inner frame 404 and an actuator platform 462. A portion of the outer side surface 418c of the inner frame 404 can be slanted to be approximately parallel to the longitudinal axis, L, of each of the flexural beams 406. The actuator platform 462 provides a surface against which the actuator 108 exerts a force in the direction of motion 401. The actuator platform 462 is coupled to the inner side surface 416c of the outer frame 402 by a lateral support beam 464 and a direct support beam 466. The actuator platform 462 can provide a rigid and stable connection surface for the actuator 108. As illustrated, a connection surface 467 of the actuator platform 462 can be approximately parallel to the longitudinal axes, L, of the flexural beams 406 and approximately perpendicular to the direction of motion 401. The lateral support beam 464 extends from the actuator platform 462 to the outer frame 402 approximately parallel to the connection surface 467 and approximately perpendicular to the direction of motion 401. The lateral support beam 464 can operate to provide a stiffness in a direction that is approximately perpendicular to the direction of motion 401 in order to prevent the actuator platform 462 from moving laterally when the actuator 108 is operating. The direct support beam 466 extends from the actuator platform 462 to the outer frame 402 approximately perpendicular to the connection surface 467 and approximately parallel to the direction of motion 401. The direct support beam 466 can operate to provide a stiffness in the direction of motion 401 in order to transfer the force from the actuator to the outer frame 402.

While FIG. 4A illustrates the actuator platform 462 including the lateral support beam 464 and the direct support beam 466, one skilled in the art will realize the actuator platform 462 can be formed in any configuration to provide a surface against which the actuator 108 exerts a force. For example, the actuator platform 462 can be formed as a solid plate or frame that is an extension of the outer frame 402.

While FIG. 4A illustrates the actuator 108 being positioned between top portions (inner side surface 416c and outer side surface 418c) of the outer frame 402 and the inner frame 404, one skilled in the art will realize that the actuator 108 can be positioned between the outer frame 402 and the inner frame 404 at any position that delivers a force in the direction of motion 401. For example, the actuator 108 can be positioned between bottom portions (inner side surface 416d and outer side surface 418d) of the outer frame 402 and the inner frame 404 to deliver a force in the direction of motion 401. Additionally, while FIG. 4A illustrates one actuator 108, one skilled in the art will realize that the support structure 400 can include additional actuators 108 to delivery forces to produce motion, for example, in the direction of motion 401.

FIG. 4B illustrates an expanded top view C of one of the flexural beams 406. While not illustrated, the flexural beams 406 can constructed having dimensions of length, l, height, h, and depth, b, as described above. As illustrated in FIG. 4B, the outer frame 402 includes one or more shelves 408 formed on the inner surface 416a for coupling the flexural beams 406 to the outer frame 402. Likewise, the inner frame 404 includes one or more shelves 408 formed on the outer surface 418a for coupling the flexural beams 406 to the inner frame 404. Each of the shelves 408 includes a connection surface 410. The connection surface 410 provides a connection point for the flexural beams 406. As illustrated in FIG. 4B, the connection surface 410 is formed to be approximately parallel to the direction of motion 401. As such, the longitudinal axis, L, of each of the flexural beams 406 is approximately perpendicular to the direction of motion 401.

In this embodiment, the support structure 400 (the outer frame 402, the inner frame 404, and the flexural beams 406) can be constructed or fabricated as a single integrated structure. For example, the outer frame 402, the inner frame 404, and the flexural beams 406 can be milled into a single integrated structure from a single piece of material (e.g., metal) or cast or molded, among other possibilities. Likewise, for example, the outer frame 402, the inner frame 404, and the flexural beams 406 can be 3D printed as a single integrated structure. In this embodiment, the outer frame 402, the inner frame 404, and the flexural beams 406 can also be fabricated separately and assembled to form the support structure 400.

While not illustrated, the support structure 400 can include connector holes formed on the inner frame 404, the outer frame 402, or combinations of both, as described above. The connector holes provide a connection point for connecting the inner frame 404 to a fixed surface, in aspects of the invention wherein the inner frame 404 is a fixed frame portion. Likewise, the connector holes provide a connection point for connecting the outer frame 402 to a fixed surface, in aspects of the invention wherein the outer frame 402 is a fixed frame portion.

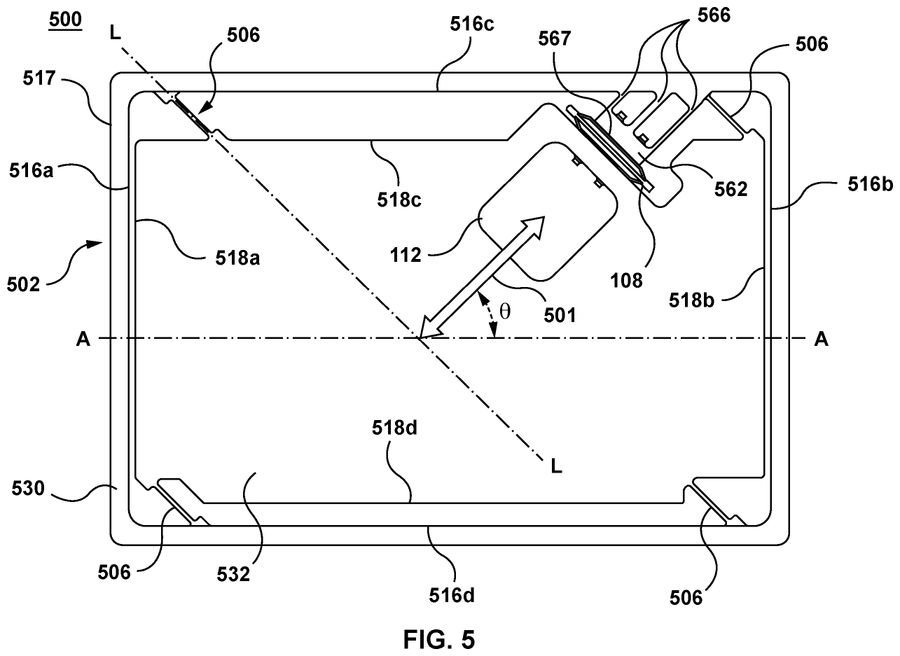

FIG. 5 illustrates another example of a support structure 500 in accordance with an embodiment hereof. One skilled in the art will realize that FIG. 5 illustrates one example of a support structure and that existing components illustrated in FIG. 5 may be removed and/or additional components may be added to the support structure without departing from the scope of embodiments described herein. In FIG. 5, a description of components with the same reference number can be found above in the description of FIGS. 1A-1F, and the same description applies to these components in FIG. 5.

As illustrated, the support structure 500 includes an outer frame 502 and an inner frame 504. In this embodiment, the outer frame 502 will be discussed as operating as the “suspended frame portion,” and the inner frame 504 will be discussed as operating as the “fixed frame portion.” The outer frame 502 is coupled to the inner frame 504 by a number of support members (e.g., flexural beams 506). In this embodiment, the outer frame 502 is coupled to the inner frame 504 by four (4) flexural beams 506. The arrangement of the flexural beams 506 (their number and positioning) between the suspended frame (e.g., the outer frame 502) and fixed frame (e.g., inner frame 504) defines the degrees of freedom of oscillation for the suspended frame. In certain circumstances, the arrangement will provide one degree of freedom which will provide a linear direction of motion of oscillation for the suspended frame. In this embodiment, the flexural beams 506 are coupled between the outer frame 502 that produces motion with one degree of freedom in a direction of motion 501 relative to the axis, A, and an angle, θ. That is, the flexural beams 506 produces harmonic oscillation in the direction of motion 501 that is approximately perpendicular to a longitudinal axis, L, of each of the flexural beams 506.

The outer frame 502 includes inner side surfaces 516a, 516b, 516c, 516d and a peripheral outer side surface 517. The outer frame 502 also includes a front surface 530. The inner frame 504 includes outer side surfaces 518a, 418b, 518c, 518d. The outer frame 504 also includes a front surface 532. One end of a flexural beam 506 is coupled to the inner side surface 516c, 516d of the outer frame 502, and one end of the flexural beam 506 is coupled to the outer side surface 518c, 518d of the inner frame 504. Each of the flexural beams 506 can be positioned having a longitudinal axis, L, in the same direction to produce the movement in the direction of motion 501, as illustrated in FIG. 5.

While FIG. 5 illustrates the flexural beams 506 being arranged alongside outer side surfaces 518c, 518d of the inner frame 504 to generate motion in the direction of motion 501, one skilled in the art will realize that the flexural beams 106 can be along the outer side surfaces 518a, 418b of the inner frame 504 to generate a direction of motion in a different direction. In this embodiment, the actuator 108 can be positioned at the outer side surfaces 518a, 518b of the inner frame 504 to deliver a force in the direction of motion 501. Likewise, an angle between the longitudinal axis, L, and the inner side surface 516c, 516d, and the outer side surface 518c, 518d, can be changed to change the direction of motion 501.

In this embodiment, the actuator 108 is coupled to the inner frame 504 and an actuator platform 562. A portion of the outer side surface 518c of the inner frame 504 can be slanted to be approximately parallel to the longitudinal axis, L, of each of the flexural beams 506. The actuator platform 562 provides a surface against which the actuator 108 exerts a force in the direction of motion 501. The actuator platform 562 is coupled to the inner side surface 516c of the outer frame 502 by direct support beams 566. The actuator platform 562 can provide a rigid and stable connection surface for the actuator 108. As illustrated, a connection surface 567 of the actuator platform 562 can be approximately parallel to the longitudinal axes, L, of the flexural beams 506 and approximately perpendicular to the direction of motion 501. The direct support beams 566 extends from the actuator platform 562 to the outer frame 502 approximately perpendicular to the connection surface 567 and approximately parallel to the direction of motion 501. The direct support beam 566 can operate to provide a stiffness in the direction of motion 501 in order to transfer the force from the actuator 108 to the outer frame 502.

While FIG. 5 illustrates the actuator platform 562 including the direct support beams 566, one skilled in the art will realize the actuator platform 562 can be formed in any configuration to provide a surface against which the actuator 108 exerts a force. For example, the actuator platform 562 can be formed as a solid plate or frame that is an extension of the outer frame 502.

While FIG. 5 illustrates the actuator 108 being positioned between top portions (inner side surface 516c and outer side surface 518c) of the outer frame 502 and the inner frame 504, one skilled in the art will realize that the actuator 108 can be positioned between the outer frame 502 and the inner frame 504 at any position that delivers a force in the direction of motion 501. For example, the actuator 108 can be positioned between bottom portions (inner side surface 516d and outer side surface 518d) of the outer frame 502 and the inner frame 504 to deliver a force in the direction of motion 501. Additionally, while FIG. 4A illustrates one actuator 108, one skilled in the art will realize that the support structure 400 can include additional actuators 108 to delivery forces to produce motion, for example, in the direction of motion 401.

While not illustrated, the flexural beams 506 can be constructed having dimensions of length, l, height, h, and depth, b, as described above. As discussed above, the outer frame 502 can includes one or more shelves formed on the inner surfaces 516c, 516d for coupling the flexural beams 506 to the outer frame 502. Likewise, the inner frame 504 includes one or more shelves formed on the outer surfaces 518c, 518d for coupling the flexural beams 506 to the inner frame 504. Each of the shelves includes a connection surface. The connection surface provides a connection point for the flexural beams 506. The connection surface can be formed to be approximately parallel to the direction of motion 501. As such, the longitudinal axis, L, of each of the flexural beams 506 can be approximately perpendicular to the direction of motion 501.

In this embodiment, the support structure 500 (the outer frame 502, the inner frame 504, and the flexural beams 506) can be constructed or fabricated as a single integrated structure. For example, the outer frame 502, the inner frame 504, and the flexural beams 506 can be milled into a single integrated structure from a single piece of material (e.g., metal) or cast or molded, among other possibilities. Likewise, for example, the outer frame 502, the inner frame 504, and the flexural beams 506 can be 3D printed as a single integrated structure. In this embodiment, the outer frame 502, the inner frame 504, and the flexural beams 506 can also be fabricated separately and assembled to form the support structure 500.

While not illustrated, the support structure 500 can include connector holes formed on the inner frame 504, the outer frame 502, or combinations of both, as described above. The connector holes provide a connection point for connecting the inner frame 504 to a fixed surface, in aspects of the invention wherein the inner frame 504 is a fixed frame portion. Likewise, the connector holes provide a connection point for connecting the outer frame 402 to a fixed surface, in aspects of the invention wherein the outer frame 502 is a fixed frame portion.

As described above, the support structures 100, 400, 500 can deliver haptic effects to an interactive device or other object coupled to the support structures 100, 400, 500.

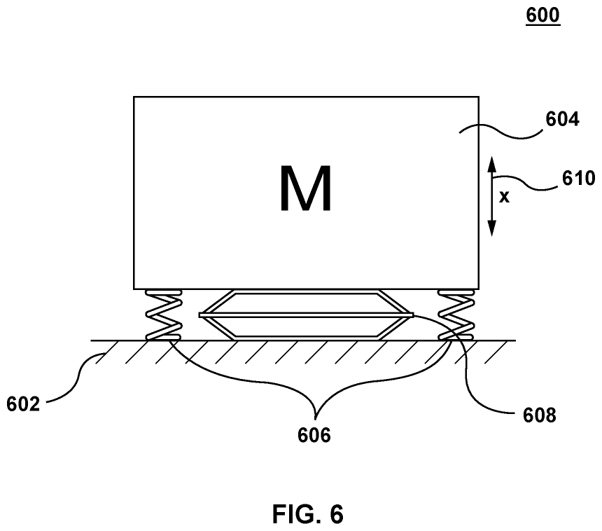

In embodiments, the support structures 100, 400, 500 together with an actuator can operate as linear resonant actuators (“LRAs”). For example, an LRA operates as a simple harmonic system as a mass coupled to a suspension. FIG. 6 illustrates a simplified diagram of any of the support structures 100, 400, 500 operating as an LRA 600.

As illustrated in FIG. 6, the LRA 600 includes a fixed portion 602 coupled to a mass 604 by a suspension 606 with an actuator 608 to impart motion. The simple harmonic motion is driven by an actuator 608 (or other source of an applied force). In embodiments, the support structures 100, 400, 500 operate as an LRA 600. For example, referring to support structure 100, the fixed frame portion (e.g., the outer frame 102 or the inner frame 104) operates as the fixed portion 602 and the suspended frame portion (e.g., the outer frame 102 or the inner frame 104 including attached interactive device, flexural beams, and portion of the actuator) operates as the mass 604. The flexural beams 106 operate as the suspension 606 to create simple harmonic motion in the direction of motion 610. As such, any of the support structures 100, 400, 500 together with one or more actuators can operate as an LRA 600.

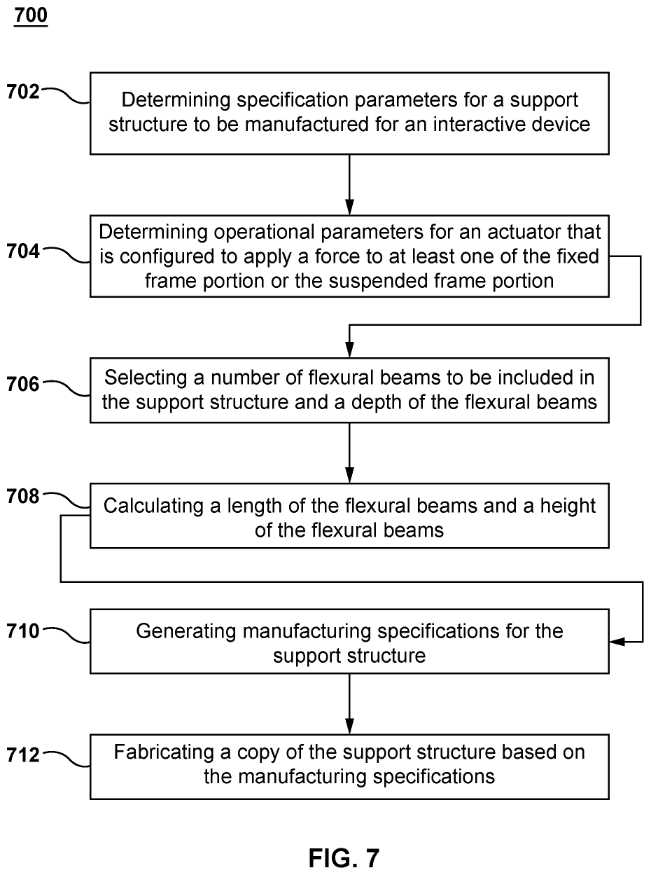

FIG. 7 is a flow chart showing a method 700 of designing and manufacturing a support structure. One or more of the steps of the method 700 can be performed on a computer system having one or more physical processors programmed with computer program instructions that, when executed by the one or more physical processors, cause the computer system to perform the method. The one or more physical processors are referred to below as simply the processor.

In 702, specification parameters can be determined for a support structure to be manufactured for the interactive device. In embodiments, the support structure 100, 400, 500 can include a fixed frame portion (e.g., the inner frame 104 or the outer frame 102), a suspended frame portion (e.g., the inner frame 104 or the outer frame 102), and one or more support members (e.g., the flexural beams 106, 406, 506) coupled between the fixed frame portion and the suspended frame portion. In embodiments, specification parameters can include any variable and/or constraint associated with the structural requirements and the motion of the support structure (e.g., the support structure 100). For example, as described in Table 1, the specification parameters of the support structure 100 can include the natural frequency of the harmonic oscillation of the suspended frame portion, an operating frequency of the harmonic oscillation of the suspended frame portion, a mass of the suspended frame portion, a mass of the interactive device, a peak acceleration of the suspended frame portion during movement in the direction of motion, a module of elasticity for a material forming the support structure 100, and a fatigue strength of the material forming the support structure 100.

In 704, operational parameters can be determined for an actuator that is configured to apply a force to at least one of the fixed frame portion or the suspended frame portion. In embodiments, the force can cause the suspended frame portion to oscillate relative to the fixed frame portion in a direction of motion, and the one or more flexural beams can provide a restoring force that causes the suspended frame portion to undergo harmonic oscillation in the direction of motion in response to the force applied by the actuator. In embodiments, the operational parameters can include any variable and/or constraint associated with the operation of the actuator 108. For example, the operational parameters of the actuator 108 can include a spring stiffness of the actuator 108.

In 706, a number of flexural beams are selected to be included in the support structure and a depth of the flexural beams is selected. In embodiments, the depth of the one or more flexural beams 106 can extend in a direction approximately perpendicular to the direction of motion 109, and the depth can be selected to control a movement of the suspended frame portion in one or more other directions. In embodiments, the number of flexural beams 106 can be selected according to the requirements of delivering haptic effects to the interactive device and/or manufacturing requirements (e.g., predefined, selected through testing, selected from manufacturing constraints, etc.).

In 708, a length of the flexural beams is calculated, and a height of the flexural beams is calculated. In embodiments, the length, l, and the height, h, are calculated using equations (27)-(31) based on the specification parameters, operational parameters, the number, n, of the one or more flexural beams, and the depth, b, of the one or more flexural beams 106. In embodiments, the length, l, of the one or more flexural beams 106 extends in a direction between the fixed frame portion and the suspended frame portion, and the height, h, of the one or more flexural beams extend in the direction of motion, and the length, l, and height, h, are calculated to allow the harmonic oscillation at a natural frequency, fₙ.

It should be understood that one or more of steps 704 through 708 can be performed in an iterative manner, so as to form a type of sub-loop, in order to optimize the parameters for the desired specification parameters. This may be done using Finite Element Analysis (FEA) among other optimization tools.

In 710, manufacturing specifications for the support structure are generated. In embodiments, the manufacturing specifications can include any necessary information to manufacture the support structure 100. For example, the manufacturing specification can include dimensions of the support structure 100 (e.g., dimensions of the outer frame 102, dimensions of the inner frame 104, number and dimensions of the flexural beams 106), identification and installation process for the actuator 108, and any information from the specification parameters and operational parameters. In some embodiments, the manufacturing specifications may include program code suitable for being executed by a 3D printing machine for printing the support structure.

In optional step 712, a copy of the support structure is fabricated based on the manufacturing specifications. For example, the outer frame 102, the inner frame 104, and the flexural beams 106 can be milled into a single integrated structure from a single piece of material (e.g., metal) or cast or molded. Likewise, for example, the outer frame 102, the inner frame 104, and the flexural beams 106 can be 3D printed as a single integrated structure. In some embodiments, the outer frame 102, the inner frame 104, and the flexural beams 106 can be fabricated separately and assembled to form the support structure 100.

Additional discussion of various embodiments is presented below:

Embodiment 1 is a support structure for an interactive device. The support structure includes a fixed frame portion configured to provide a fixed connection point for the support structure. The support structure also includes a suspended frame portion configured to support the interactive device and configured to oscillate in a direction of motion relative to the fixed frame portion due to a force applied to at least one of the fixed frame portion or the suspended frame portion by an actuator configured to provide a haptic effect to the interactive device. Further, the support structure includes one or more support members coupled between the fixed frame portion and the suspended frame portion. The direction of motion is defined by the one or more support members. The one or more support members provide a restoring force that causes the suspended frame portion to undergo harmonic oscillation in the direction of motion in response to the force applied by the actuator.

Embodiment 2 includes the support structure of embodiment 1, wherein the one or more support members enable motion with one degree of freedom and provides resistance to motion in all other degrees of freedom.

Embodiment 3 includes the support structure of any of embodiments 1 or 2, wherein a first end of a support member of the one or more support members is coupled to an outer side surface of the fixed frame portion and a second end of the support member is coupled to an inner side surface of the suspended frame portion.

Embodiment 4 includes the support structure of embodiment 3, wherein the one or more support members include one or more flexural beams.

Embodiment 5 includes the support structure of embodiment 4, wherein a flexural beam of the one or more flexural beams includes a first structural fillet formed in one or more corners of the first end of the flexural beam where it is coupled to the outer side surface of the fixed frame portion, and a second structural fillet formed in one or more corners of the second end of the flexural beam where it is coupled to the inner side surface of the suspended frame portion.

Embodiment 6 includes the support structure of any of embodiments 4 or 5, wherein the flexural beam includes a length extending in a direction between the fixed frame portion and the suspended frame portion, a height extending in the direction of motion, and a depth extending perpendicular to the height, and the flexural beam is formed to have a ratio of the depth to the height that allows harmonic oscillation and minimizes the movement of the suspended frame portion in the one or more other directions.

Embodiment 7 includes the support structure of any of embodiments 4-6, wherein the fixed frame portion includes a shelf formed on the outer side surface of the fixed frame portion, and the first end of the flexural beam is coupled to a connection surface of the shelf of the fixed frame portion at an angle of approximately 90 degrees. The suspended frame portion includes a shelf formed on the inner side surface of the suspended frame portion, and the second end of the flexural beam is coupled to a connection surface of the shelf of the suspended frame portion at an angle of approximate 90 degrees. The connection surface of the shelf of the fixed frame portion and the connection surface of the shelf of the suspended frame portion is approximately parallel to the direction of motion, and the direction of motion is approximately 45 degrees to a horizontal axis of the support structure.

Embodiment 8 includes the support structure of any of embodiments 4-7, wherein the flexural beam has at least one of a rectangular cross-section, a circular cross-section, an oval cross-section, and a potato-like cross-section.

Embodiment 9 includes the support structure of any of embodiments 1-8, wherein the suspended frame portion is formed as a hollow frame comprising at least first and second inner side surfaces, the fixed frame portion is formed interior to the suspended frame portion with at least first and second outer side surfaces, and the first and second inner side surfaces of the suspended frame portion oppose the first and second outer side surfaces of the fixed frame portion, respectively.

Embodiment 10 includes the support structure of embodiment 9, wherein a first of the one or more support members is coupled to the first outer side surface of the fixed frame portion and a second of the one or more support members is coupled to the second outer side surface of the fixed frame portion at a position opposing the first of the one or more support members.

Embodiment 11 includes the support structure of any of embodiments 1-10, wherein the fixed frame portion, the suspended frame portion, and the one or more flexural beams are a single integrated structure.

Embodiment 12 includes the support structure of any of embodiments 1-12, wherein one or more of the fixed frame portion, the suspended frame portion, or the support members are formed of a flexible material.

Embodiment 13 includes the support structure of any of embodiments 1-13, wherein the support structure with an actuator operates as a linear resonant actuator.

Embodiment 14 is a method of manufacturing a support structure for an interactive device. The method includes determining specification parameters for a support structure to be manufactured for the interactive device. The support structure includes a fixed frame portion, a suspended frame portion, and one or more support members coupled between the fixed frame portion and the suspended frame portion. The method also includes determining operational parameters of an actuator that is configured to apply a force to at least one of the fixed frame portion or the suspended frame portion to cause the suspended frame portion to oscillate relative to the fixed frame portion in a direction of motion. A configuration of the one or more support members provide a restoring force that causes the suspended frame portion to undergo harmonic oscillation in the direction of motion in response to the force applied by the actuator. Further, the method includes selecting a number of the one or more support members to be included in the support structure and a depth of the one or more support members, the depth extending in a direction approximately parallel to the direction of motion. The method also includes determining a length of the one or more support members and a height of the one or more support members based on the specification parameters, operational parameters, the number of the one or more support members, and the depth of the one or more support members.

Embodiment 15 includes the method of embodiment 14, wherein the method also includes calculating a total spring stiffness of a harmonic system created by the support structure, calculating a spring stiffness of the one or more support members, and calculating an amplitude of displacement of the one or more support members.

Embodiment 16 includes the method of any of embodiments 14 or 15, wherein the specification parameters of the support structure comprise the natural frequency of the harmonic oscillation of the suspended frame portion, an operating frequency of the harmonic oscillation of the suspended frame portion, a mass of the suspended frame portion, a mass of the interactive device, a peak acceleration of the suspended frame portion during movement in the direction of motion, a module of elasticity for a material forming the support structure, and a fatigue strength of the material forming the support structure.

Embodiment 17 includes the method of any of embodiments 14-16, wherein the operational parameters of the actuator comprise a spring stiffness of the actuator.

Embodiment 18 includes the method of any of embodiments 14-17, wherein the method also includes fabricating a copy of the support structure according to the manufacturing specifications.

Embodiment 19 includes the method of embodiment 18, wherein the copy of the support structure is fabricated as a single integrated structure.

Embodiment 20 is a haptic enabled system. The system includes an interactive device, an actuator, and a support structure coupled to the interactive device to provide a haptic effect to the interactive device. The support structure includes a suspended frame portion configured to support the interactive device. To provide the haptic effect, the suspended frame portion oscillates in a direction of motion relative to a fixed frame portion due to a force applied to the suspended frame portion by the actuator. The support structure also includes one or more support members coupled between the suspended frame portion and the fixed frame portion. The direction of motion is defined by the one or more support members. The one or more support members provide a restoring force that causes the suspended frame portion to undergo harmonic oscillation in the direction of motion in response to the force applied by the actuator.

As used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C). While various embodiments according to the present disclosure have been described above, it should be understood that they have been presented by way of illustration and example only, and not limitation. It will be apparent to persons skilled in the relevant art that various changes in form and detail can be made therein without departing from the spirit and scope of the present disclosure. Thus, the breadth and scope of the present disclosure should not be limited by any of the above-described exemplary embodiments but should be defined only in accordance with the appended claims and their equivalents. It will also be understood that each feature of each embodiment discussed herein, and of each reference cited herein, can be used in combination with the features of any other embodiment. Stated another way, aspects of the above methods of encoding haptic tracks may be used in any combination with other methods described herein or the methods can be used separately. All patents and publications discussed herein are incorporated by reference herein in their entirety.

What is claimed is:

1. A support structure for an interactive device, the support structure comprising:
a fixed frame portion configured to provide a fixed connection point for the support structure;
a suspended frame portion configured to support the interactive device and configured to oscillate in a direction of motion relative to the fixed frame portion due to a force applied to at least one of the fixed frame portion or the suspended frame portion by an actuator configured to provide a haptic effect to the interactive device; and
one or more support members coupled between the fixed frame portion and the suspended frame portion, wherein
the direction of motion is defined by the one or more support members, and
the one or more support members provide a restoring force that causes the suspended frame portion to undergo harmonic oscillation in the direction of motion in response to the force applied by the actuator.

2. The support structure of claim 1, wherein the one or more support members enables motion with one degree of freedom and provides resistance to motion in all other degrees of freedom.

3. The support structure of claim 1, wherein a first end of a support member of the one or more support members is coupled to an outer side surface of the fixed frame portion and a second end of the support member is coupled to an inner side surface of the suspended frame portion.

4. The support structure of claim 3, wherein the one or more support members comprise one or more flexural beams.

5. The support structure of claim 4, wherein a flexural beam of the one or more flexural beams comprises:
a first structural fillet formed in one or more corners of the first end of the flexural beam where it is coupled to the outer side surface of the fixed frame portion; and
a second structural fillet formed in one or more corners of the second end of the flexural beam where it is coupled to the inner side surface of the suspended frame portion.

6. The support structure of claim 4, wherein the flexural beam comprises a length extending in a direction between the fixed frame portion and the suspended frame portion, a height extending in the direction of motion, and a depth extending perpendicular to the height, and
wherein the flexural beam is formed to have a ratio of the depth to the height that allows harmonic oscillation and minimizes the movement of the suspended frame portion in the one or more other directions.

7. The support structure of claim 4, wherein the fixed frame portion comprises a shelf formed on the outer side surface of the fixed frame portion, and the first end of the flexural beam is coupled to a connection surface of the shelf of the fixed frame portion at an angle of approximately 90 degrees,
wherein the suspended frame portion comprises a shelf formed on the inner side surface of the suspended frame portion, and the second end of the flexural beam is coupled to a connection surface of the shelf of the suspended frame portion at an angle of approximate 90 degrees,
wherein the connection surface of the shelf of the fixed frame portion and the connection surface of the shelf of the suspended frame portion is approximately parallel to the direction of motion,
wherein the direction of motion is approximately 45 degrees to a horizontal axis of the support structure.

8. The support structure of claim 4, wherein the flexural beam has at least one of a rectangular cross-section, a circular cross-section, an oval cross-section, and a potato-like cross-section.

9. The support structure of claim 1, wherein the suspended frame portion is formed as a hollow frame comprising at least first and second inner side surfaces,
wherein the fixed frame portion is formed interior to the suspended frame portion with at least first and second outer side surfaces, and
wherein the first and second inner side surfaces of the suspended frame portion oppose the first and second outer side surfaces of the fixed frame portion, respectively.

10. The support structure of claim 9, wherein a first of the one or more support members is coupled to the first outer side surface of the fixed frame portion and a second of the one or more support members is coupled to the second outer side surface of the fixed frame portion at a position opposing the first of the one or more support members.

11. The support structure of claim 1, wherein the fixed frame portion, the suspended frame portion, and the one or more flexural beams are a single integrated structure.

12. The support structure of claim 1, wherein one or more of the fixed frame portion, the suspended frame portion, or the support members are formed of a flexible material.

13. The support structure of claim 1, wherein the support structure with an actuator operates as a linear resonant actuator.

14. A method of manufacturing a support structure for an interactive device, the method comprising:
determining specification parameters for a support structure to be manufactured for the interactive device, the support structure comprising a fixed frame portion, a suspended frame portion, and one or more support members coupled between the fixed frame portion and the suspended frame portion;
determining operational parameters of an actuator that is configured to apply a force to at least one of the fixed frame portion or the suspended frame portion to cause the suspended frame portion to oscillate relative to the fixed frame portion in a direction of motion, wherein a configuration of the one or more support members provide a restoring force that causes the suspended frame portion to undergo harmonic oscillation in the direction of motion in response to the force applied by the actuator;
selecting a number of the one or more support members to be included in the support structure and a depth of the one or more support members, the depth extending in a direction approximately parallel to the direction of motion, and
determining a length of the one or more support members and a height of the one or more support members based on the specification parameters, operational parameters, the number of the one or more support members, and the depth of the one or more support members.

15. The method of claim 14, further comprising:
calculating a total spring stiffness of a harmonic system created by the support structure;
calculating a spring stiffness of the one or more support members; and
calculating an amplitude of displacement of the one or more support members.

16. The method of claim 14, wherein the specification parameters of the support structure comprise the natural frequency of the harmonic oscillation of the suspended frame portion, an operating frequency of the harmonic oscillation of the suspended frame portion, a mass of the suspended frame portion, a mass of the interactive device, a peak acceleration of the suspended frame portion during movement in the direction of motion, a module of elasticity for a material forming the support structure, and a fatigue strength of the material forming the support structure.

17. The method of claim 14, wherein the operational parameters of the actuator comprise a spring stiffness of the actuator.

18. The method of claim 14, the method further comprising:
fabricating a copy of the support structure according to the manufacturing specifications.

19. The method of claim 18, wherein the copy of the support structure is fabricated as a single integrated structure.

20. A haptic enabled system, the system comprising:
an interactive device;
an actuator; and
a support structure coupled to the interactive device to provide a haptic effect to the interactive device, the support structure comprising
a suspended frame portion configured to support the interactive device, wherein, to provide the haptic effect, the suspended frame portion oscillates in a direction of motion relative to a fixed frame portion due to a force applied to the suspended frame portion by the actuator; and
one or more support members coupled between the suspended frame portion and the fixed frame portion, wherein:
the direction of motion is defined by the one or more support members, and
the one or more support members provide a restoring force that causes the suspended frame portion to undergo harmonic oscillation in the direction of motion in response to the force applied by the actuator.
